(19) United States
(12) Patent Application Publication
(10) Pub. No.: US 2022/0295634 A1
(43) Pub. Date: Sep. 15, 2022

(54) PRINTED CIRCUIT BOARD AND MANUFACTURING METHOD THEREFOR, AND TERMINAL

(71) Applicant: SPREADTRUM COMMUNICATIONS (SHANGHAI) CO., LTD., Shanghai (CN)

(72) Inventors: Yuanyuan CAI, Shanghai (CN); Zhigang WANG, Shanghai (CN)

(21) Appl. No.: 17/828,568

(22) Filed: May 31, 2022

Related U.S. Application Data
(63) Continuation of application No. PCT/CN2020/114147, filed on Sep. 9, 2020.

(30) Foreign Application Priority Data
Dec. 30, 2019 (CN) 201911397549.8

(51) Int. Cl. H05K 1/14; H05K 3/36

(52) U.S. Cl. CPC H05K 1/142; H05K 3/36; H05K 2201/048; H05K 2201/049; H05K 2203/0207

(57) ABSTRACT

A Printed Circuit Board (PCB), a method for manufacturing a PCB, and a terminal are provided. The PCB includes: a PCB daughter board which is a Radio Frequency (RF) PCB; and a PCB mother board with a hollow slot, wherein the PCB daughter board is embedded in the hollow slot.

### CROSS-REFERENCE TO RELATED APPLICATIONS

This application is a continuation under 35 U.S.C. § 120 of PCT/CN2020/114147, filed on Sep. 9, 2020, which is incorporated herein by reference, and which claimed priority to Chinese Patent Application No. 201911397549.8, filed on Dec. 30, 2019, and entitled “PRINTED CIRCUIT BOARD AND MANUFACTURING METHOD THEREFOR, AND TERMINAL”. The present application likewise claims priority under 35 U.S.C. § 119 to Chinese Application No. 201911397549.8, filed Dec. 30, 2019, the entire content of which is also incorporated herein by reference.

### TECHNICAL FIELD

The present disclosure generally relates to Printed Circuit Board (PCB) technology field, and more particularly, to a PCB and a manufacturing method thereof, and a terminal.

### BACKGROUND

Exiting modules are usually designed by a single-sided layout and surface-mounted mother board. Specifically, for most of traditional data modules, a single-sided layout is subjected to a module Leadless Chip Carriers (LCC) or Land Grid Array (LGA) package, and then is surface-mounted on a PCB motherboard. Surface mount is low in cost and easy to be promoted on a large scale. However, as the PCB of the data module is relatively large, a thickness of a product is increased after surface mount, which does not meet a requirement of small thickness of electronic products.

As communication products such as mobile phones enter the 5G era from the 2G, 3G and 4G eras, project cycles and risks of product development have also increased. Especially for 5G Radio Frequency (RF) modules, a large number of resistive components need to be used due to a large number of RF frequency bands. Compared with 3G and 4G RF modules, a debugging cycle of 5G RF modules is much longer, and thus a debugging workload and difficulty become higher.

### SUMMARY

By embodiments of the present disclosure, an RF PCB with a relatively small thickness may be obtained.

In an embodiment of the present disclosure, a PCB is provided, including: a PCB daughter board which is a Radio Frequency (RF) PCB; and a PCB mother board with a hollow slot, wherein the PCB daughter board is embedded in the hollow slot.

In an embodiment of the present disclosure, a method for manufacturing a PCB is provided, including: providing a PCB mother board and a PCB daughter board, wherein the PCB mother board includes a hollow slot, and the PCB daughter board is an RF PCB; and embedding the PCB daughter board into the hollow slot.

In an embodiment of the present disclosure, a terminal including the above PCB is provided.

### BRIEF DESCRIPTION OF THE DRAWINGS

FIG. 1 is a structural diagram of a PCB in existing techniques.

FIG. 2 is a structural diagram of another PCB in existing techniques.

FIG. 3 is a structural diagram of a PCB according to an embodiment.

FIG. 4 is a structural diagram of a PCB according to an embodiment.

FIG. 5 is a structural diagram of a PCB according to an embodiment.

FIG. 6 is a flow chart of a method for manufacturing a PCB according to an embodiment.

### DETAILED DESCRIPTION

As described in the background, exiting data modules are usually designed by a single-sided layout and surface-mounted motherboard. Due to the design of single-sided layout, an area of a corresponding PCB is relatively large. Besides, a thickness of a product is relatively great.

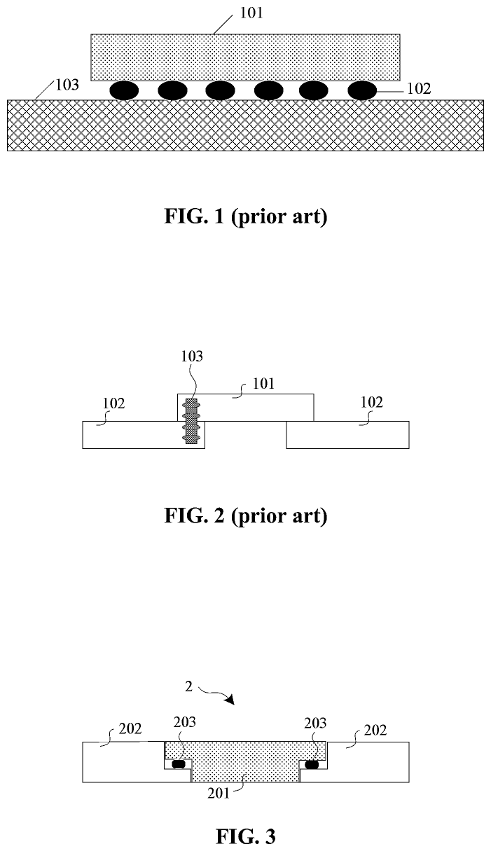

FIG. 1 is a structural diagram of a PCB in existing techniques. Referring to FIG. 1, a PCB includes a PCB daughter board 101, a PCB mother board 103 and a plurality of solder balls 102. In the PCB, the PCB daughter board 101 is surface-attached to the PCB mother board 103, and is fixed by the solder balls 102, which requires low cost. However, this assembly method can only be laid out on one side, causing a too large area, and even tripling a layout area of the PCB, and a PCB area of the data module obtained by the surface mount is too large, which may also increase a thickness of a product after the surface mount. This assembly welding method may aggravate reflection and loss problems caused by high-speed digital signals and RF signals passing stubs.

FIG. 2 is a structural diagram of another PCB in existing techniques. Referring to FIG. 2, a PCB includes a PCB daughter board 101, a PCB mother board 102 and a half stamp hole-type soldering pin 103. In the PCB, the PCB daughter board 101 is surface-attached to the PCB mother board 102 and is fixed by the half stamp hole-type soldering pin 103. Due to the half stamp hole-type soldering pin 103, reflection and loss problems caused by high-speed digital signals and RF signals passing stubs may occur.

In embodiments of the present disclosure, a PCB is provided, including: a PCB daughter board which is an RF PCB; and a PCB mother board with a hollow slot, wherein the PCB daughter board is embedded in the hollow slot.

When used in conjunction with the PCB mother board, the PCB provided by the embodiments of the present disclosure can be embedded in the hollow slot of the PCB mother board, so that a double-sided layout replaces a single-sided layout, to make a size of the RF PCB (for example, an RF PCB of a 5G system) be reduced, and a thickness of a whole product be not increased after the assembly is completed.

In order to clarify the objects, characteristics and advantages of the disclosure, embodiments of present disclosure will be described in detail in conjunction with accompanying drawings.

FIG. 3 is a structural diagram of a PCB according to an embodiment. Referring to FIG. 3, the PCB 2 has a structure in which the PCB mother board and daughter board are inter-embedded, so that a data module can be laid out on both sides, which helps to save an area of the PCB for the module. For example, the data module may be an RF module.

The PCB 2 includes a PCB daughter board 201 and a PCB mother board 202. The PCB daughter board 201 is an RF PCB, and the PCB mother board 202 has a hollow slot (not shown). The PCB daughter board 201 is embedded in the hollow slot.

In some embodiments, the PCB daughter board 201 is formed by hollowing out an edge of an original RF PCB, wherein the edge of the original RF PCB includes a part of the original RF PCB that needs to be assembled and connected with the PCB mother board and does not involve any region within an RF circuit shield.

In some embodiments, the PCB daughter board 201 is formed by hollowing out the edge of the original RF PCB using a depth-controlled milling technique. In the depth-controlled milling technique, a milling cutter is adopted to mill out a certain depth of stepped slots on the PCB without milling through the PCB.

In some embodiments, the hollow slot is formed by a depth-controlled milling technique, and a size of the hollow slot matches a size of the PCB daughter board 201.

In some embodiments, an outer contour of the PCB daughter board 201 is in a T-shape, and an outer contour of the hollow slot is in an inverted convex shape or an inverted T-shape.

In some embodiments, the PCB mother board 202 may be soldered to the PCB daughter board 201 via soldering pads 203. Two protruding ends of the PCB daughter board 201 may be soldered to two protruding parts of the PCB mother board 202, respectively.

To clearly show a boundary between the PCB daughter board 201 and the PCB mother board 202, in FIG. 3, the PCB mother board 202 and the PCB daughter board 201 have a small gap therebetween. However, in practice, the hollow slot of the PCB mother board 202 can just have the PCB daughter board 201 embedded, and the hollow slot and the PCB daughter board 201 are closely attached to each other on a vertical cutting plane.

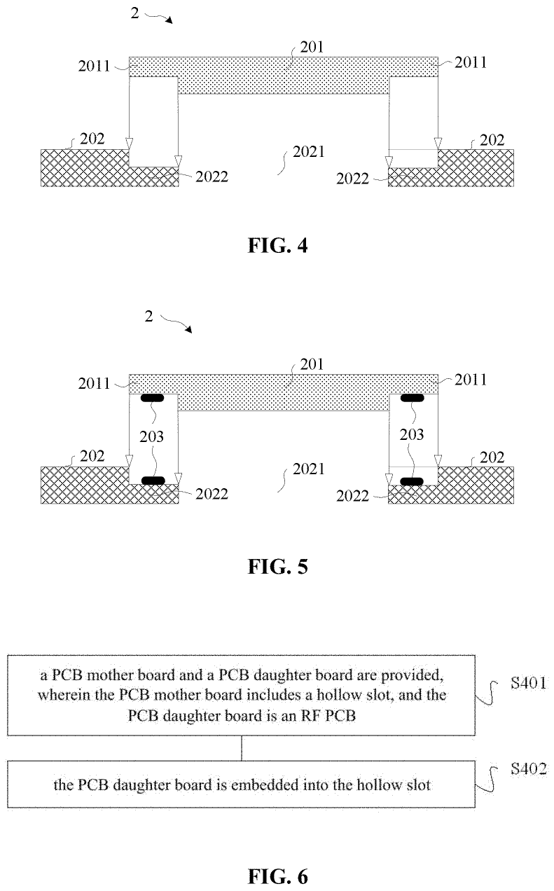

FIG. 4 is a structural diagram of a PCB according to an embodiment. Referring to FIG. 4, the PCB 2 has a structure in which the PCB mother board and daughter board are inter-embedded, which helps to save an area of the PCB for a module.

Specifically, the PCB 2 includes a PCB daughter board 201 and a PCB mother board 202. The PCB daughter board 201 is an RF PCB, and the PCB mother board 202 has a hollow slot 2021. The PCB daughter board 201 is embedded in the hollow slot 2021. As shown in FIG. 4, the PCB daughter board 201 may be embedded in the hollow slot 2021 of the PCB mother board 202 along an arrow direction.

In some embodiments, the PCB daughter board 201 is formed by hollowing out an edge of an original RF PCB, wherein the edge of the original RF PCB includes a part of the original RF PCB that needs to be assembled and connected with the PCB mother board and does not involve any region within an RF circuit shield.

In some embodiments, the PCB daughter board 201 is formed by hollowing out the edge of the original RF PCB using a depth-controlled milling technique.

In some embodiments, the hollow slot 2021 is formed by a depth-controlled milling technique, and a size of the hollow slot 2021 matches a size of the PCB daughter board 201.

In some embodiments, an outer contour of the PCB daughter board 201 is in a T-shape, and an outer contour of the hollow slot 2021 is in an inverted convex shape.

In some embodiments, the PCB mother board 202 may be soldered to the PCB daughter board 201 via soldering pads (not shown). Two protruding ends of the PCB daughter board 201 may be soldered to two protruding parts of the PCB mother board 202, respectively.

In some embodiments, the protruding parts 2022 of the PCB mother board 202 are center-symmetrical, and the protruding ends 2011 of the PCB daughter board 201 are center-symmetrical as well. The two protruding ends 2011 of the PCB daughter board 201 are respectively soldered to the center-symmetrical protruding parts 2022.

Further, the PCB 2 may be debugged, and after the debugging is completed, the PCB 2 may reduce a research and development cycle and risk of RF module products of 5G and subsequently evolved wireless communication systems, thereby reducing overall research and development cost and facilitating promotion and application.

FIG. 5 is a structural diagram of a PCB according to an embodiment. In following descriptions, descriptions on matters and features common to the above embodiment as shown in FIG. 4 are omitted, and merely differences are described. In the figures, the same part is marked with the same reference numeral.

Referring to FIG. 5, the two protruding ends 2011 of the PCB daughter board 201 are soldered to the two protruding parts 2022 via soldering pads 203, respectively. By assembling and matching the mother board and daughter board, reflection and loss problems caused by high-speed digital signals and RF signals passing stubs may be mitigated.

Still referring to FIG. 5, the protruding parts 2022 of the PCB mother board 202 are center-symmetrical, and the protruding ends 2011 of the PCB daughter board 201 are center-symmetrical as well. The two protruding ends 2011 of the PCB daughter board 201 are respectively soldered to the protruding parts 2022.

Further, the PCB 2 may be debugged, and after the debugging is completed, the PCB 2 may reduce a research and development cycle and risk of RF module products of 5G and subsequently evolved wireless communication systems, thereby reducing overall research and development cost and facilitating promotion and application.

From above, the PCB provided in the embodiments of the present disclosure may reduce a research and development cycle and risk of 5G RF module products. Besides, a double-sided layout replaces a single-sided layout, thereby greatly reducing a size of the PCB for the module, and a thickness of a mobile communication product, such as a cellphone. Using the RF PCB provided in the embodiments of the present disclosure may reduce an overall cost and facilitate promotion and application.

FIG. 6 is a flow chart of a method for manufacturing a PCB according to an embodiment.

Referring to FIG. 6, the method may include S401 and S402.

In S401, a PCB mother board and a PCB daughter board are provided, wherein the PCB mother board includes a hollow slot, and the PCB daughter board is an RF PCB.

In S402, the PCB daughter board is embedded into the hollow slot.

In some embodiments, in S401, an original PCB mother board and an original PCB daughter board are provided, wherein the original PCB daughter board is a PCB including an RF circuit.

In some embodiments, an edge of the original PCB daughter board may be hollowed out to obtain the PCB daughter board, wherein the edge refers to a part of the original RF PCB that needs to be assembled and connected with the PCB mother board and does not involve any region within an RF circuit shield.

In some embodiments, the edge of the original PCB daughter board may be hollowed out using a depth-controlled milling technique. An outer contour of the PCB daughter board subjected to the hollowing is in a T-shape.

Afterward, the original PCB mother board may be preprocessed to obtain a to-be-milled part which is used to be embedded in the PCB daughter board. In some embodiments, the PCB mother board may be hollowed out using the depth-controlled milling technique, to mill the to-be-milled part to obtain the PCB mother board with a hollow slot.

In some embodiments, an outer contour of the hollow slot is in an inverted convex shape, and a size of the hollow slot matches a size of the PCB daughter board.

In S402, the PCB daughter board may be embedded in the hollow slot, and a thickness of the obtained PCB is generally not increased. For example, initial thickness of the PCB daughter board and the PCB mother board are the same. After the PCB daughter board is embedded in the hollow slot, the thickness of the obtained PCB is the same as the PCB mother board.

In some embodiments, the PCB mother board includes two protruding parts, and the PCB daughter board includes two protruding ends. One of the two protruding ends is controlled to be soldered to one of the two protruding parts, and the other protruding end is controlled to be soldered to the other protruding part.

In an embodiment of the present disclosure, a terminal is provided, including any one of the PCBs as shown in FIG. 3 to FIG. 5. In some embodiments, the terminal may be a 5G terminal or a subsequently evolved wireless system terminal.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure.

What is claimed is:

1. A Printed Circuit Board (PCB), comprising:
a PCB daughter hoard which is a Radio Frequency (RF) PCB; and
a PCB mother board with a hollow slot,
wherein the PCB daughter board is embedded in the hollow slot.

2. The PCB according to claim 1, wherein the PCB daughter board is formed by hollowing out an edge of an original RF PCB, wherein the edge of the original RF PCB comprises a part of the original RF PCB that needs to be assembled and connected with the PCB mother board and does not involve any region within an RF circuit shield.

3. The PCB according to claim 2, wherein the PCB daughter board is formed by hollowing out the edge of the original RF PCB using a depth-controlled milling technique.

4. The PCB according to claim 1, wherein the hollow slot is formed by a depth-controlled milling technique, and a size of the hollow slot matches a size of the PCB daughter board.

5. The PCB according to claim 4, wherein an outer contour of the PCB daughter board is in a T-shape, and an outer contour of the hollow slot is in an inverted convex shape.

6. The PCB according to claim 4, wherein the PCB mother board comprises two protruding parts, and the PCB daughter board comprises two protruding ends, wherein one of the two protruding ends is soldered to one of the two protruding parts via a soldering pad, and the other protruding end is soldered to the other protruding part via a soldering pad.

7. A method for manufacturing a Printed Circuit Board (PCB), comprising:
providing a PCB mother board and a PCB daughter board, wherein the PCB mother board comprises a hollow slot, and the PCB daughter board is an RF PCB; and
embedding the PCB daughter board into the hollow slot.

8. The method according to claim 7, wherein prior to embedding the PCB daughter board into the hollow slot, the method further comprises:
hollowing out an edge of an original RF PCB to obtain the PCB daughter board, wherein the edge of the original RF PCB comprises a part of the original EU PCB that needs to be assembled and connected with the PCB mother board and does not involve any region within an RF circuit shield.

9. The method according to claim 8, wherein said hollowing out 71 edge of an original RF PCB comprises:
hollowing out the edge of the original RF PCB using a depth-controlled milling technique.

10. The method according to claim 7, wherein the hollow slot is formed by a depth-controlled milling technique, and a size of the hollow slot matches a size of the PCB daughter board.

11. The method according to claim 10, wherein an outer contour of the PCB daughter board is in a T-shape, and an outer contour of the hollow slot is in an inverted convex shape.

12. The method according to claim 10, wherein the PCB mother board comprises two protruding parts, the PCB daughter board comprises two protruding ends, and the method further comprises:
controlling the two protruding ends to be soldered to the two protruding parts, respectively.

13. A terminal, comprising a Printed Circuit Board (PCB), wherein the PCB comprises:
a PCB daughter board which is a Radio Frequency (RF) PCB; and
a PCB mother board with a hollow slot,
wherein the PCB daughter board is embedded in the hollow slot.

14. The terminal according to claim 13, wherein the PCB daughter board is formed by hollowing out an edge of an original RF PCB, wherein the edge of the original RF′ PCB comprises a part of the original RF PCB that needs to be assembled and connected with the PCB mother board and does not involve any region within an RF circuit shield.

15. The terminal according to claim 14, Wherein the PCB daughter board is formed by hollowing out the edge of the original RF PCB using a depth-controlled milling technique.

16. The terminal according to claim 13, wherein the hollow slot is formed by a depth-controlled milling technique, and a size of the hollow slot matches a size of the PCB daughter board.

17. The terminal according to claim 16, wherein an outer contour of the PCB daughter board is in a T-shape, and an outer contour of the hollow slot is in an inverted convex shape.

18. The terminal according to claim 16, wherein the PCB mother board comprises two protruding parts, and the PCB daughter board comprises two protruding ends, wherein one of the two protruding ends is soldered to one of the two protruding parts via a soldering pad, and the other protruding end is soldered to the other protruding part via a soldering pad.
